(19) United States
(12) Patent Application Publication
(10) Pub. No.: US 2003/0152863 A1
(43) Pub. Date: Aug. 14, 2003

(54) Photostructured paste

(76) Inventors: Claudio De La Prieta, Stuttgart (DE); Thomas Schulte, Stuttgart (DE); Uwe Glanz, Asperg (DE); Petra Kuschel, Renningen (DE)

Correspondence Address: KENYON & KENYON, ONE BROADWAY, NEW YORK, NY, 10004, US

(21) Appl. No.: 10/221,995

(22) PCT Filed: Mar. 8, 2001
(86) PCT No.: PCT/DE01/00867

(30) Foreign Application Priority Data
Mar. 14, 2000 (DE) 100 15 502.2

(51) Int. Cl. G03F 7/038

(52) U.S. Cl. 430/270.1

(57) ABSTRACT

A photostructurable paste is proposed which is particularly suitable for manufacturing structured resistor layers or printed circuit traces on ceramic blank substrates. In this context, the paste has a light-sensitive organic binder and a filler material, the binder including a polymer, a photoinitiator, an inhibitor for a thermal polymerization, an organic disulfide and an organic solvent. The filler material is a platinum powder, a platinum compound or a mixture of a platinum powder or a platinum compound with a ceramic powder or a ceramic precursor compound.

The present invention relates to a photostructurable paste, especially for producing structured resistor layers or printed circuit traces on ceramic blanks, according to the generic concept of the main claim.

### BACKGROUND INFORMATION

The so-called “Fodel technique”, developed by DuPont, is known for manufacturing structured resistor layers or printed circuit traces on ceramic blanks, which, for example, are made to be zigzag-shaped or meander-shaped from place to place.

Going into detail, in this instance a paste is printed on ceramic blank substrates which is subsequently structured by exposure to UV rays and using a photomask. After this structuring there follows development of the paste in the exposed areas. However, it is a disadvantage with this technique that a yellow room is always required, since the pastes are sensitive to daylight. Also, the known pastes based on the Fodel technique are suitable only for temperatures up to a maximum of 900° C., i.e. the ceramic blank substrates furnished with the applied and structured pastes may thereafter be fired or sintered at a maximum of 900° C. However, these temperatures are often not sufficient. In addition, using the Fodel technique, it is not possible simultaneously to generate coarse and very fine structurings on the blank substrates.

In addition, it is also known that one may apply platinum-containing pastes on ceramic substrates that have already been fired, instead of ceramic blank substrates, and that these may then be provided with structured functional layers by using photostructuring. Using this technique makes possible fine structuring up to lateral dimensions of ca 10 μm, while when using conventional screen printing techniques only structures having lateral expansions of 100 μm may be produced.

In Application DE 199 34 109.5 producing a temperature sensor was proposed, in which first of all meander-shaped printed circuit traces or resistor runs made of platinum are applied to ceramic blank substrates, which are then constructed together with further ceramic blank substrates in the form of a multilayer hybrid, and are then sintered to form a temperature sensor using a co-firing technique. However, because of the usual thick-layer technique used there, it is only possible to realize printed circuit trace widths and printed circuit trace distances apart of 0.2 mm.

Because the known platinum-containing, photostructurable pastes may only be applied to ceramics that have already been fired, such processes and pastes are not able to be integrated into existing production methods, in which, up to now, ceramic blank substrates are always printed, for example, by using a screen printing technique. In addition to this, the resolution that can be achieved using a screen printing technique is limited to 100 μm, as was explained.

In Lithuanian Application LT-97 161, a photostructurable, platinum-containing paste was proposed in this connection, which is suitable for being applied to a ceramic substrate that has already been fired, and which may be structured by photostructuring after being applied. Using this, one may achieve structural resolutions of typically 10 μm to 30 μm.

Starting from Application LT-97 161, it was the object of the present invention to modify the photostructurable paste proposed in that document in such a way that it is also suitable for direct application to ceramic blank substrates. At the same time, it was the object of the present invention to make available a photostructurable paste which would make possible a clear increase in structural resolution while simultaneously staying with the co-firing technology, for producing multi-layer structures or multi-layer hybrids. This procedure is supposed to ensure the simplest possible integration into existing production lines.

### SUMMARY OF THE INVENTION

Compared to the related art, the photostructurable paste according to the present invention has the advantage that ceramic blank substrates may be directly furnished with functional layers which are subsequently structurable, in the form of printed circuit traces or resistor runs, by photostructuring. Lateral resolutions of less than 50 μm, especially between 5 μm and 25 μm are thereby attained.

Besides such an absolute lateral resolution of the structures produced, the paste, according to the present invention, has the further advantage, that the structures remaining on the ceramic blank after photostructuring have only a low standard deviation of the lateral expansion of the produced structures, in at least one dimension, from a predefined setpoint value. This being the case, even broader structures than 50 μm may be produced, which then, however, have, for example, a very accurately specified width. The standard deviation from the setpoint value is usually less than 10 μm, in particular less than 5 μm.

The paste according to the present invention is thus advantageously suitable for producing multi-layer structures on a ceramic base, ceramic blanks being first furnished with a structured functional layer, which are then processed further to become hybrid components.

Thus, using the paste according to the present invention, the temperature sensor known from Application DE 199 34 109.5 may also be produced, having considerably improved properties with respect to the resistor runs.

The platinum-containing paste according to the present invention further has the advantage that it is stable over time, and does not crumble even under irradiation with daylight, in spite of the addition of the catalytically very active platinum.

Furthermore, it is advantageous that, for the filler used in the photostructurable paste, instead of pure platinum powder, a mixture of platinum powder with aluminum oxide powder and/or zirconium dioxide powder may also be used. This mixture leads to an improvement in the adhesion of the produced Pt printed circuit trace to the blank (“green tape”) and/or aids in increasing the electrical resistance of printed circuit traces manufactured in this manner, for instance by mixing Pt powder particles with Al₂O₃ powder particles.

Advantageous further refinements of the present invention result from the measures indicated in the dependent claims.

Thus, it is advantageous that the photosensitive paste may be developed by an aqueous solution, and that it has a low sensitivity to visible light and the influence of oxygen. These properties mean a considerable simplification of the method technique during processing and structuring of the paste, since, for example, one does not have to work in yellow light rooms or under the exclusion of oxygen.

By the substantially improved resolution attainable by using the paste according to the present invention, for example, resistor runs may be produced in meander structures on ceramic blanks, and thus also on fired ceramic substrates obtained after termination of the sintering of these blanks, which, compared to comparable resistor runs, produced by conventional thick film technique, have increases in resistance of more than 400%. The resistor printed circuit traces thus produced, when used in temperature sensors or heating elements signify a clearly lower area requirement at simultaneously improved accuracy of temperature measurement and greater measuring resistance, i.e. improved accuracy in measuring voltage evaluation.

Because of the increased resolution during photostructuring of the paste according to the present invention, another result is clearly reduced fluctuations in the resistors of the resistor printed circuit traces, so that overall one achieves a higher manufacturing quality, less scrap and lower deviations, of the resistances aimed for, from the predefined setpoint value.

### DESCRIPTION OF THE EXEMPLARY EMBODIMENTS

The present invention is based on a photostructurable paste such as that already described in a similar form in Lithuanian Patent Application LT-97 161. However, the photostructurable paste described there is suitable only for being applied to already fired ceramic substrates, and therefore has to be modified for application to ceramic blank substrates. This modification is substantially based on the fact that, in the paste composition known from LT-97 161, the glass components required there, in the form of glass powder particles, are removed, or rather are not added when mixing together the paste.

Thus it was discovered surprisingly, that the photosensitive paste known from LT-97 161 is suitable for direct application to ceramic blanks if one modifies the paste composition described there to the extent that the glass powder components are not added. It was further discovered that a photosensitive paste thus modified permits directly the production of structured functional layers on ceramic blank substrates, the lateral expansion of the structures produced in these functional layers by photostructuring lying at least in one dimension, such as the width, below 50 μm, in particular between 5 μm and 25 μm. It was determined at the same time that even when one wants to produce broader structures, these can be produced with a clearly increased precision. A measure of this precision is the standard deviation of the lateral expansion of the structures produced, in at least one dimension, from a predefined setpoint value. This standard deviation typically lies below 10 μm, especially under 5 μm.

As filler material for the photostructurable paste according to the present invention a platinum powder having an average particle size of 10 nm to 20 μm, especially of 50 nm to 2 μm, is particularly suitable. Also, the specific surface of the inorganic filler material and/or the platinum powder is preferably 0.5 m²/g through 20 m²/g.

The proportion overall of the inorganic filler material in the photostructured paste lies between 30% through 90%, based on the total weight of the paste. A weight proportion of 50% to 60% is preferred.

Especially preferred is the addition of a mixture of platinum powder having a ceramic powder as inorganic filler material in the photostructured paste. In this connection, the ceramic powder also has, comparable to the platinum powder, an average particle size and a specific surface of 10 nm through 20 μm and 0.5 m²/g through 20 m²/g, respectively. Aluminum oxide powder, zirconium dioxide powder, yttrium-stabilized zirconium dioxide powder, yttrium oxide powder, titanium dioxide powder, silicon oxide powder or a mixture of these powders are especially used as the ceramic powder. However, platinum-coated, nonconducting ceramic particles may additionally be used as filler material. By the addition of the ceramic powder to the platinum powder, clearly higher sheet resistances result in the production of resistor printed circuit traces using the photostructurable paste. With regard to greater detail of this factual situation known in principle, we refer to Application DE 199 34 109.5.

Besides the addition of pure platinum as filler material, in principle, the addition of platinum compounds may also be considered, particularly platinum precursor compounds such as platinum(II)acetylacetonate, platinum(II)diaminocyclobutane-1,1-dicarboxylate, platinum(0)-1,3-divinyl-1,1,3,3-tetramethyldisiloxane or platinum(II)tetraamino nitrate. However, for reasons of cost, these filler materials are not preferred. In addition, instead of the ceramic powders, ceramic precursor materials, in particular organic precursor materials based on Si, Al, Zr, Ti and Y may also be used. Such precursor materials are known to one skilled in the art.

In the case of the ceramic blanks or ceramic substrates onto which the photostructurable paste is applied as a functional layer, by the way, the usual ceramic blank substrates are involved having ceramic particles embedded in a polymer matrix, for instance, yttrium-stabilized zirconium dioxide particles or aluminum oxide particles.

In addition, it may also be provided that, first of all, an intermediate layer is applied before the application of the photostructurable paste onto the ceramic blank. This intermediate layer is, for instance, an Al₂O₃ layer or a TiO₂ layer, each known per se.

It should be further emphasized that, after the application of the photostructurable paste on the ceramic blank, and its structuring by exposure and subsequent development, a further processing of the ceramic blank pretreated in this manner is performed, for example, resulting in multi-layer hybrid components.

Thus, on the whole it is possible, using the photostructurable paste described in more detail below, to generate structured functional layers on ceramic blank substrates which are insensitive to the visible spectrum of light and the inhibiting effect of oxygen, and which stand out by their great photopolymerization speed and an excellent line resolution. In addition, the paste according to the present invention may also be processed with the aid of the known thick-layer technology.

The polymer used in the organic binder is particularly important for the paste. This polymer has to be a photochemically active polymer, i.e. it not only plays the role in the binder of a layer-forming component and a component conveying solubility, but is at the same time also supposed to really initiate the photopolymerization by an initiator insensitive to the visible spectrum of light. For this purpose it is formed as a large molecular, polyfunctional monomer. At the same time, the side chains of the polymer with its allyl groups, and the organic disulphide additionally included in the organic binder, neutralize the inhibiting effect of oxygen. In this manner it is ensured that all technological operations may be carried out, i.e. the preparation of the light-sensitive organic binder, its mixing with the filler material, the application of the paste obtained onto a ceramic blank substrate, subsequent drying, photostructuring and developing in daylight or in usual artificial light. In addition, one needs no special precautions for avoiding contact of the photostructurable paste with oxygen present in the air.

During the process of polymerization, by the way, the linearly shaped macromolecules of the polymers used in the binder, which have side chains having alkyl groups and allyl groups, form a dense spatial structure, so that, in the range of the exposed locations, the polymer is completely insoluble in aqueous solvents. A particularly short exposure time comes about, by the way, because of the added photoinitiator from the class of azylphosphine. In total, the photostructurable paste has the following composition in proportion by mass based on the mass of the inorganic filler material:

| | |
|---|---|
| filler material | 100.00 |
| polymer | 9.00 to 36.00 |
| photoinitiator | 0.50 to 3.50 |
| organic disulfide | 0.20 to 2.00 |
| inhibitor of thermal polymerization | 0.01 to 0.35 |
| organic solvent | 5.50 to 21.50 |

A series of demands are placed on the polymer contained in the organic binder. Thus, for instance, it should be soluble in water-soluble base solutions, form a non-adhering skin or membrane at room temperature, it should make it possible to set the viscosity of the photostructurable paste, and it should actively participate in the photoinitiating, radical polymerization in an oxygen-containing environment. Finally, thermal decomposition of the polymer should occur even at temperatures that are as low as possible.

These requirements are best satisfied by acrylic or vinyl monomers and unsaturated carboxylic acid copolymers, their molecular weight preferably lying between 10,000 and 20,000, and the mass of the unsaturated carboxylic acid in the copolymer being between 15 and 30 mass %. With respect to further details concerning the requirements on, and the possibilities of the various usable polymers we refer to Lithuanian Application LT-97 161.

Since the usable polymers have side chains having acrylic and allyl groups, they clearly lessen the sensitivity of the organic binder to the inhibiting effect of oxygen, but they do not completely eliminate it. That is why it is further necessary to add an organic disulfide whose general formula is R₁—CH₂—S—S—CH₂—R₂ for the same or various alkyl, cycloalkyl, aryl, arylalkyl or carboxylalkyl radicals. Didodecyldisulfide is particularly suitable as the organic disulfide.

A photoinitiator from the class of acyl phosphine is added to the photostructurable paste as photoinitiator. The preferred compound is 2,6-dimethoxybenzoyldiphenylphosphine.

The solvent added for setting the viscosity of the photostructurable paste should, first of all, very well dissolve all the organic components, at the same time have low volatility at room temperature,and evaporate relatively quickly at temperatures from 80° C.-100° C., since such temperatures are typically used when drying ceramic blank substrates, particularly after applying the photostructurable paste.

Terpenes, carbitol acetate or the higher alcohol esters are preferred as solvents. Benzyl alcohol is particularly preferred. In order to ensure the stability of the photostructurable paste during the drying process, it is also necessary to add an inhibitor for thermal polymerization. The compound 2,6-di-tert-butyl-1,4-cresol has proven to be a particularly suitable inhibitor.

The processing of the individual components of the photostructurable paste was accomplished in a manner essentially as known from Lithuanian LT-97 161. In this context, first of all, the components of the organic binder were stirred with the filler, for example in a three-roll mill, so as to ensure a uniform distribution of the filler particles in the organic binder. The photostructurable paste prepared in this manner is then applied, in a manner known per se, to a ceramic blank substrate having aluminum oxide as the ceramic component, in the form of a functional layer having a typical thickness of 1 μm through 10 μm.

After that, the blank substrates furnished with functional layers were dried at a temperature of 800° C.-100° C. over a time of typically 5 min to 20 min, and were finally exposed to UV light with the use of a photomask. The photomask for this procedure is structured, for example, in the form of meander-shaped resistor printed circuit traces.

The UV light for the exposure preferably has a wavelength of 320 nm-400 nm.

After the exposure of the areas of the functional layer not covered by the photomask, there followed the development of the photostructurable paste. For this, for example, an aerosol of an aqueous 0.5% monoethanolamine solution is dripped upon a support, on which the exposed blank substrates are situated, which rotates at a speed of typically 3000 revolutions per minute. This method is commonly known as spin development, and is explained in greater detail in Lithuanian LT-97 161.

After the development of the photostructurable paste, the nonexposed areas are finally washed again with a water-soluble base solution.

The further processing of the ceramic blank substrates having upon them the developed, photostructurable paste is then performed using the method known from Application DE 199 34 109.5. Thus, the ceramic blank substrates furnished with the structured functional layers, if necessary, are stacked up with further ceramic blank substrates, provided with through-hole hole plating and electrical contacts, and finally are sintered at temperatures of typically 1050° C. to 1650° C.

What is claimed is:

1. A photostructurable paste, in particular for manufacturing structured resistor layers or pinted circuit traces on ceramic blank elements, having a filler material and a light-sensitive organic binder which includes a polymer, a photoinitiator, an inhibitor for a thermal polymerization, an organic disulfide and an organic solvent, the filler material being a platinum powder, a platinum compound or a mixture of a platinum powder or a platinum compound with a ceramic powder or with a ceramic precursor compound.

2. The photostructurable paste as recited in claim 1,
wherein the polymer is a membrane-forming polymer.

3. The photostructurable paste as recited in claim 1,
wherein the organic binder is free of polyfunctional monomers and the polymer is photochemically active.

4. The photostructurable paste as recited in claim 1,
wherein the filler material is free of glass powder.

5. The photostructurable paste as recited in claim 1,
wherein the platinum powder and/or the ceramic powder have an average particle size of 10 nm through 20 μm, in particular 20 nm through 5 μm, and a specific surface of 0.5 m²/g through 20 m²/g.

6. The photostructurable paste as recited in at least one of the preceding claims,
wherein the filler material is added in a proportion of 30% through 90% based on the total weight of the paste.

7. The photostructurable paste as recited in at least one of the preceding claims,
wherein the ceramic powder is an Al₂O₃ powder, an in particular yttrium-stabilized ZrO₂ powder, a Y₂O₃ powder, a TiO₂ powder, an SiO₂ powder or a mixture of these powders.

8. The photostructurable paste as recited in at least one of the preceding claims,
wherein the components of the paste are included in the following mass proportions based on the mass of the inorganic filler material:

| | |
|---|---|
| filler material | 100.00 |
| polymer | 9.00 to 36.00 |
| photoinitiator | 0.50 to 3.50 |
| organic disulfide | 0.20 to 2.00 |
| inhibitor of thermal polymerization | 0.01 to 0.35 |
| organic solvent | 5.50 to 21.50 |

9. The photostructurable paste as recited in at least one of the preceding claims,
wherein after exposure, the paste may be developed using a water-soluble base solution.

10. The photostructurable paste as recited in at least one of the preceding claims,
wherein the inorganic filler material and the organic binder are dispersed in the paste.

11. The photostructurable paste as recited in at least one of the preceding claims,
wherein the polymer is a copolymer of alkylacrylates and alkylmethacrylates, whose alkyl groups have 1 through 12 carbon atoms; and/or the polymer is a copolymer of cycloalkyl(meth)acrylates, arylalkyl(meth)acrylates, styrol, acrylonitrile or their mixtures and unsaturated carboxylic acids, whose free carboxyl groups are verestert with 2,3-epoxypropyl(meth)acrylate and/or allylglycidylether.

12. The photostructurable paste as recited in claim 1 or 11,
wherein the polymer is a copolymer of styrol and acrylic acid and has in particular 15 mass % of non-esterified acrylic acid, 15 mass % acrylic acid, esterified with 2,3-epoxypropylmethacrylate, and 6 mass % allylglycidyl ether; or the polymer is a copolymer of butylmethacrylate and methacrylic acid and has in particular 15 mass % non-esterified methacrylic acid, 20 mass % methacrylic acid, esterified with 2,3-epoxypropylmethacrylate and 7.5 mass % allylglycidyl ether.

13. The photostructurable paste as recited in at least one of the preceding claims,
wherein the photoinitiator is 2,6-dimethoxybenzoyldiphenylphosphine, the organic solvent is benzyl alcohol, the organic disulfide is didodecyl disulfide, and the inhibitor of the thermal polymerization is 2,6-di-tert-butyl-1,4-cresol.
